(19) United States
(12) Patent Application Publication
(10) Pub. No.: US 2006/0242508 A1
(43) Pub. Date: Oct. 26, 2006

(54) Simultaneous scan testing for identical modules

(75) Inventors: Neil John Simpson, Rockwall, TX (US); Divya Reddy, Richardson, TX (US); Hari Balachandran, Allen, TX (US)

Correspondence Address: TEXAS INSTRUMENTS INCORPORATED, P O BOX 655474, M/S 3999, DALLAS, TX, 75265, US

(73) Assignee: Texas Instruments Incorporation, Dallas, TX (US)

(21) Appl. No.: 11/115,459

(22) Filed: Apr. 26, 2005

(51) Int. Cl. G01R 31/28

(52) U.S. Cl. 714/726

(57) ABSTRACT

A system 100 for scan testing at least two substantially identical modules 140 and 150 within an integrated circuit is provided. The system 100 includes a first module 140 to receive and process scan input and produce a first scan output. The system 100 includes a second module 150 substantially similar to the first module 140. The second module 150 receives and processes scan input and produces a second scan output. The system 100 also includes a first component 180 to receive the first and second scan outputs and to produce a first output. The first output is used to determine whether the first and second modules 140 and 150 are functioning properly.

### CROSS-REFERENCE TO RELATED APPLICATIONS

None.

### STATEMENT REGARDING FEDERALLY SPONSORED RESEARCH OR DEVELOPMENT

Not applicable.

### REFERENCE TO A MICROFICHE APPENDIX

Not applicable.

### FIELD OF THE INVENTION

The present invention relates to scan testing of integrated circuits. More particularly, embodiments of the present invention allow two or more substantially identical modules to be tested simultaneously using the same test patterns and testing resources.

### BACKGROUND OF THE INVENTION

A scan chain, a serially connected set of flip-flops, is sometimes embedded in an integrated circuit chip to facilitate testing of the chip prior to its delivery to a customer. To test an integrated circuit by means of a scan chain, a pattern of data is serially clocked into the chain of flip-flops. On the first clock pulse of a series of clock pulses, the first flip-flop in the chain accepts a data bit. For example, a bit of data moves from the input to the output of the flip-flop. Since the output of the first flip-flop is the input of the second flip-flop, the first bit of data is then present at the input of the second flip-flop. At the second clock pulse, the data bit that was at the input of the second flip-flop moves to the output of that flip-flop and the first flip-flop accepts a new bit of data. Data continues to move in this manner through the chain of flip-flops until the first bit of data reaches the last flip-flop. This serial input of data into a scan chain is known as the shift mode.

After the shift mode is complete, the scan chain can enter the capture mode. In capture mode, the data bits at the outputs of the flip-flops are moved in parallel fashion into the logic circuits of the integrated circuit chip. The logic circuits then manipulate the data and the resulting data is moved in parallel fashion back to the flip-flops. A shift mode is then re-entered and the data is shifted out of the flip-flops one bit at a time in a manner similar to the way data was shifted in. The data that is shifted out of the flip-flops can be compared to the expected output to determine if the integrated circuit logic performed as expected in manipulating the data.

As used herein, the terms “scan test”, “scan testing”, and the like refer to the testing of integrated circuits in the manner described above. “Scan input” refers to a stream of binary data that is entered into an integrated circuit to perform a scan test and “scan output” refers to the stream of binary data that is produced by a scan test. “Input” and “output” can also refer to physical points in a digital circuit into which binary data is entered and from which binary data is produced.

The symbols “0” and “1” are used herein as they are commonly used by those of skill in the art to refer to binary data values. The binary values might represent the absence or presence, or approximate absence or presence, of a voltage or might represent some other physical attribute typically manipulated by a digital circuit. Regardless of the actual physical characteristic represented, a “0” or a “1” is intended to symbolize a value that might appear in one of the truth tables commonly associated with the standard logic gates well known in the art.

### SUMMARY OF THE INVENTION

According to one embodiment, a system is provided for scan testing at least two substantially identical modules within an integrated circuit. The system includes a first module to receive and process scan input and produce a first scan output. The system includes a second module substantially similar to the first module. The second module receives and processes scan input and produces a second scan output. The system also includes a first component to receive the first and second scan outputs and to produce a first output. The first output is used to determine whether the first and second modules are functioning properly.

In an alternative embodiment, a system is provided for scan testing at least two substantially identical modules within an integrated circuit. The system includes a scan input, a first module, and a second module. The first module is operable to receive and process the scan input and produce a first scan output. The second module is substantially similar to the first module. The second module is operable to receive and process the scan input and produce a second scan output. The system also includes a means for receiving the first and second scan outputs and producing a first output. The first output used to determine whether the first and second modules are functioning properly.

In another embodiment, a method is provided for determining whether at least two substantially identical modules within an integrated circuit are functioning properly. The method includes sending a scan input to a first module and a second module. The method includes producing a first scan output by the first module, and producing a second scan output by the second module. The method includes sending the first and second scan outputs to a first component, and producing a first output by the first component. The method also includes using the first output to determine whether the first and second modules are functioning properly.

These and other features and advantages will be more clearly understood from the following detailed description taken in conjunction with the accompanying drawings and claims.

### BRIEF DESCRIPTION OF THE DRAWINGS

For a more complete understanding of the presentation and the advantages thereof, reference is now made to the following brief description, taken in connection with the accompanying drawings in detailed description, wherein like reference numerals represent like parts.

FIG. 1 is a block diagram of an embodiment of an electronic circuit for simultaneous scan testing of two identical modules.

FIG. 2 is a block diagram of another embodiment of an electronic circuit for simultaneous scan testing of two identical modules.

FIG. 3 is a block diagram of an embodiment of an electronic circuit for simultaneous scan testing of three identical modules.

FIG. 4 is a block diagram of an embodiment of an electronic circuit for simultaneous scan testing of four identical modules.

### DETAILED DESCRIPTION OF THE PREFERRED EMBODIMENTS

It should be understood at the outset that although an exemplary implementation of one embodiment is illustrated below, the present system may be implemented using any number of techniques, whether currently known or in existence. The present disclosure should in no way be limited to the exemplary implementations, drawings, and techniques illustrated below, including the exemplary design and implementation illustrated and described herein, but may be modified within the scope of the appended claims along with their full scope of equivalents.

A particular set of logic gates interconnected in a particular manner within an integrated circuit can be referred to as a module. It is possible for identical or substantially identical modules to be present at multiple locations within a single chip. Due to their similarities, these modules may be viewed or referred to herein as functionally equivalent or identical, identical or substantially identical modules although these modules may not necessarily be exactly physically or otherwise identical to one another. Two techniques have traditionally been used to perform scan testing on multiple identical modules. In one technique, the same test is performed separately on each module and the outcome of each test is analyzed individually. In the other technique, the identical modules might be combined into a single effective module and a scan test might be performed on the larger effective module. Both of these options can be inefficient due to the redundancy of the test procedures.

A testing technique that makes use of a circuit design that can be referred to as a minority encoder can make the testing of multiple identical modules more efficient. An example of a minority encoder is disclosed in U.S. Patent Application Publication No. 2003/0079165 to Niall Ffrench et al. entitled Effective Use of Parallel Scan for Identically Instantiated Sequential Blocks filed Apr. 24, 2004, which is hereby incorporated by reference herein for all purposes as if reproduced in its entirety. A minority encoder is typically used when more than two identical modules are being tested. Identical scan inputs or sets of scan inputs are fed into the identical modules and the outputs of the modules are examined. If a majority of the modules produce the same result, that result is considered correct and all of the modules that produced that result are considered to have successfully passed the scan test.

However, when only two identical modules are present, a majority would not exist if the two modules had different scan outputs. It might not be possible to determine which of the two scan outputs is correct without relying on the traditional scan testing techniques. Therefore, the minority encoder technique might not produce reliable results when only two identical modules are present.

Embodiments of the present invention allow two identical modules in an integrated circuit to be tested simultaneously using the same test patterns and testing resources. This eliminates the redundancy of traditional scan testing techniques and the unreliability of the minority encoder technique when exactly two identical modules are being tested.

In an embodiment, identical scan inputs are applied to the scan chains within the two identical modules. If the modules are functioning properly, their outputs should be identical. The outputs from the two modules are combined into an exclusive OR (XOR) gate. If the output of the XOR gate is “0” (indicating the XOR gate had identical inputs), the two modules are considered to have passed the scan test. If there is a difference between the outputs from the two modules, the output of the XOR gate will contain a “1” and at least one of the two modules is considered to have failed the scan test. In the case of a failure, a traditional scan test can be performed on the two modules to determine which if them is faulty.

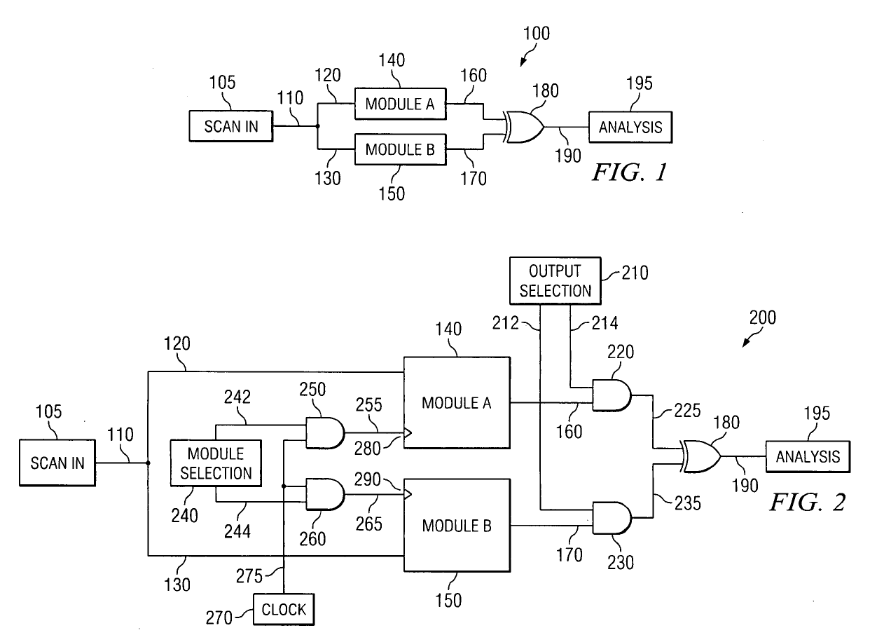

FIG. 1 illustrates an embodiment of the present invention of a circuit design 100 implementing a technique for simultaneous scan testing for identical or substantially identical modules. A scan input 110 is generated by a standard test scan generating component 105 such as those well known in the art. For the sake of simplicity in the drawing, only one scan input 110 is shown but one of skill in the art will recognize that in actual practice multiple parallel inputs are often used for scan chain testing. For example, a commonly used test scan generating component creates eight parallel outputs.

The scan input 110 is split to create two similar inputs 120 and 130. The inputs 120 and 130 send the similar series of bits into two identical or substantially identical modules, module A 140 and module B 150. A clock (not shown) ensures that the inputs 120 and 130 are synchronized. That is, when a bit enters module A 140, an identical bit enters module B 150 at approximately the same time.

Module A 140 and module B 150 process the inputs 120 and 130 and generate outputs 160 and 170. The outputs 160 and 170 are fed as inputs into a two-input XOR gate 180. The XOR gate 180 performs an exclusive OR action on its two inputs and generates an output 190. As is well known in the art, when identical inputs are fed into an XOR gate, the output is a “0”. When different inputs are fed into an XOR gate, the output is a “1”.

Only one output 160 or 170 is shown for module A 140 and for module B 150 but in actual practice a greater number of outputs would typically be present. More specifically, the number of outputs would equal the number of inputs. For example, a standard test scan generating component that sends eight parallel scan inputs to module A 140 and eight parallel scan inputs to module B 150 would produce eight scan outputs from module A 140 and eight scan outputs from module B 150.

An analysis component 195 can examine the output 190 to make the determination whether the output 190 is a “0” or a “1” and possibly take further appropriate actions. In one embodiment, the analysis component 195 is a human who measures a physical attribute of the output 190 or who observes a representation of such a physical attribute. In other embodiments, the analysis component 195 might be an automated device that can determine the value of the output 190, reach the appropriate conclusions, and take the appropriate actions based on that determination. The analysis component 195 might also be a combination of human and automated elements.

In a traditional scan testing technique, identical inputs 120 and 130 might be fed into module A 140 and module B 150 as in FIG. 1. Two steps might then be taken to test the outputs 160 and 170. First, the output 160 of module A 140 might be compared to an expected output. Then, the output 170 of module B 150 might be compared to an expected output. If both outputs 160 and 170 matched what was expected, both modules A 140 and B 150 would be considered good. If either output 160 or 170 did not match what was expected, the module A 140 or B 150 that produced the unexpected output 160 or 170 would be considered faulty.

In various embodiments, the testing of the outputs 160 and 170 is simplified. Since identical inputs 120 and 130 are fed into identical modules A 140 and B 150, identical outputs 160 and 170 should be created. The validity of the outputs 160 and 170 can then be tested by comparing the outputs 160 and 170 to each other rather than to expected outputs.

By feeding the outputs 160 and 170 into the XOR gate 180, it can be determined whether the outputs 160 and 170 are identical. That is, if the output 190 of the XOR gate 180 is a “0”, it can be assumed that the outputs 160 and 170 were substantially the same. If the output 190 of the XOR gate 180 contains a “1”, it can be assumed that a difference existed between the outputs 160 and 170.

If the output 190 of the XOR gate 180 is a “0” (that is, if the outputs 160 and 170 are the same), it can be assumed that module A 140 and module B 150 performed the same actions on the inputs 120 and 130 and that module A 140 and module B 150 are therefore both functioning properly. It can be seen that checking whether the output 190 of the XOR gate 180 is a “0” or a “1 ” is much simpler than comparing the output 160 to its expected result and then comparing the output 170 to its expected result.

It is conceivable that both module A 140 and module B 150 could have the same fault and could make the same error in processing the inputs 120 and 130. This could produce outputs 160 and 170 that are the same, but that are both incorrect. The output 190 of the XOR gate 180 would then be a “0”, suggesting that module A 140 and module B 150 are working properly when, in fact, both are faulty. However, when a long string of bits is used for the inputs 120 and 130 to module A 140 and module B 150, and when the number of operations performed by module A 140 and module B 150 is large, the likelihood of module A 140 and module B 150 both making the same error and producing the same erroneous output is extremely small.

For most practical purposes, therefore, it is safe to assume that if the outputs 160 and 170 are the same then module A 140 and module B 150 are both functioning properly. If desired, a scan test can be performed in the traditional manner on module A 140 or module B 150 after a “0” has been detected on the output 190 of the XOR gate 180. This can confirm that the modules are functioning properly.

If the output 190 of the XOR gate 180 contains a “1” (that is, if the outputs 160 and 170 are different), it can be assumed that one or both of modules A 140 and B 150 has a fault and produced an erroneous output 160 and/or 170. In such a case, individual comparisons of the outputs 160 and 170 to the expected output can be made in the traditional manner to determine which of the modules A 140 and/or B 150 is faulty.

Additional circuitry can be added to the design depicted in FIG. 1 to aid in isolating a faulty module A 140 or B 150. FIG. 2 illustrates an embodiment of one such design 200. An output selection component 210 can cause an output 160 or 170 from module A 140 or module B 150 to be blocked and cause the output of the other module to pass unchanged through the XOR gate 180. The unchanged output can then be compared in the traditional manner to the expected output. Thus, standard scan chain testing can be performed on one module A 140 or B 150 in isolation from the other module A 140 or B 150.

This is accomplished by combining an output 212 or 214 from the output selection component 210 with one of the outputs 160 or 170 from module A 140 or module B 150 in an AND gate 220 or 230. That is, output 212 from the output selection component 210 and output 170 from module B 150 are combined in AND gate 230 and output 214 from the output selection component 210 and output 160 from module A 140 are combined in AND gate 220. Output 225 from AND gate 220 and output 235 from AND gate 230 are then combined in XOR gate 180.

While only two AND gates 220 and 230 and two outputs 212 and 214 from the output selection component 210 are shown, a greater number would typically be present. As mentioned previously, module A 140 and module B 150 would each typically have multiple outputs, but in FIG. 2 only one output is shown for each module A 140 and B 150 for the sake of clarity in the drawing. The number of AND gates and the number of outputs from the output selection component 210 would typically be equal to the total number of outputs from modules A 140 and B 150.

Appropriate selection of the values of the outputs 212 and 214 from the output selection component 210 can cause the output 160 from module A 140 or the output 170 from module B 150 to appear on the output 190 of the XOR gate 180 and allow the output 160 or 170 to be analyzed in the traditional manner. As an example, a “0” might be placed on the output 212 and a “1” might be placed on the output 214. With the constant “0” from output 212 being fed into the AND gate 230, the output 235 of the AND gate 230 will be “0” regardless of the value of the output 170 from module B 150. With the constant “1” from output 214 being fed into the AND gate 220, the output 225 of the AND gate 220 will be identical to the output 160 from module A 140. Thus, one of the inputs to the XOR gate 180 is a “0” and the other input is the same as the output 160 from module A 140.

When one input to a two-input XOR gate is a “0”, the output of the XOR gate will be the same as the other input. Therefore, when a “0” is placed on the output 212 of the output selection component 210 and a “1” is placed on the output 214 of the output selection component 210, the output 160 of module A 140 passes unchanged to the output 190 of the XOR gate 180. With similar logic, it can readily be seen that placing a “0” on the output 214 of the output selection component 210 and a “1” on the output 212 of the output selection component 210, will cause the output 170 of module B 150 to pass unchanged to the output 190 of the XOR gate 180.

The addition of the output selection component 210 and the AND gates 220 and 230 to the circuit shown in FIG. 1 allows the outputs 160 and 170 from modules A 140 and B 150 to be selectively passed to or blocked from the output 190 of the XOR gate 180 and thus allows the outputs 160 and 170 to be tested in the traditional manner when desired. One of skill in the art will recognize that other arrangements of logic gates and output selection components might perform similar output selection functions.

In another embodiment, module A 140 and module B 150 might be isolated from each other through the use of a module selection component 240. The module selection component 240 can cause module A 140 to cease operation and cause module B 150 to operate normally or vice versa. In this way, the output 160 of module A 140 or the output 170 of module B 150 can selectively be sent to the output 190 of the XOR gate 180 for standard scan test analysis.

An output 242 from the module selection component 240 feeds into an AND gate 250 and another output 244 from the module selection component 240 feeds into another AND gate 260. The remaining inputs of the two-input AND gates 250 and 260 are both fed by the output 275 of a standard clock 270. The output 255 of the AND gate 250 feeds into a clock input 280 of module A 140 and the output 265 of the AND gate 260 feeds into a clock input 290 of module B 150. The clock inputs 280 and 290 control the timing of the scan inputs 120 and 130 into module A 140 and module B 150, respectively. When a “1” is present on clock input 280, a bit on the scan input 120 can enter module A 140 and when a “1” is present on clock input 290, a bit on the scan input 130 can enter module B 150.

Module A 140 or module B 150 can be selected to operate or not operate through the appropriate selection of values for the outputs 242 and 244 from the module selection component 240. As an example, a “1” might be placed on the output 242 and a “0” might be placed on the output 244. With the “1” from the output 242 as one input to the AND gate 250 and the output 275 from the clock 270 as the other input to the AND gate 250, the output 255 of the AND gate 250 will be the same as to the clock signal 275. When this output 255 is fed into the clock input 280 of module A 140, module A 140 can operate in its normal manner.

With the “0” from the output 244 as one input to the AND gate 260, the output 265 from the AND gate 260 will be “0” regardless of the value of the clock signal 275. When the “0” on the output 265 of the AND gate 260 is fed into the clock input 290 on module B 150, module B 150 will not accept the scan input 130 and thus will cease to operate. Therefore, a “1” on output 242 and a “0” on output 244 will cause module A 140 to operate normally and module B 150 to cease operation. Similarly, a “1” on output 244 and a “0” on output 242 will cause module B 150 to operate normally and module A 140 to cease operation. Selection of module A 140 or module B 150 in this manner can allow traditional scan testing to be performed on module A 140 or module B 150.

One of skill in the art will recognize that other arrangements of logic gates and module selection components might perform similar module selection functions. Also, in one embodiment, the module selection functionality might be present without the output selection functionality. In another embodiment, the output selection functionality might be present without the module selection functionality, or both the module selection and output selection functionalities might be present. In addition, it should be recognized that the module selection or output selection functionalities could be used as a backup to perform scan testing in the traditional manner in the case of a failure of the XOR gate 180.

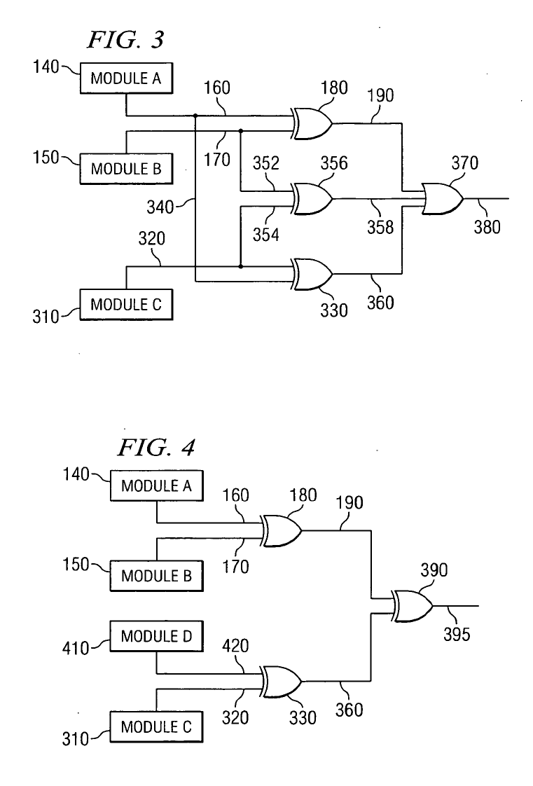

While the previous discussion has focused on scan testing for two substantially identical modules, similar circuitry and procedures could be used to test more than two modules. An example of a gate array that could be used for testing three modules is shown in FIG. 3. As in FIG. 1, the output 160 of module A 140 and the output 170 of module B 150 feed into the XOR gate 180. For the sake of clarity in the drawing, the scan inputs, the module selection and output selection circuitry, and the analysis component shown in FIG. 2 are not shown in FIG. 3, but may be assumed to be present in some embodiments.

FIG. 3 illustrates a third module, module C 310, which is substantially identical to module A 140 and module B 150. The output 320 of module C 310 feeds into one input of a two-input XOR gate 330. The other input of the XOR gate 330 is tied, via connection 340, to output 160 of module A 140.

The output 320 of module C 310 also feeds, via connection 354, into one input of a two-input XOR gate 356. The other input of XOR gate 356 is tied, via connection 352, to output 170 of module B 150.

The output 358 of XOR gate 356, the output 190 of XOR gate 180, and the output 360 of XOR gate 330 feed into a three-input OR gate 370. This arrangement effectively creates a three-input XOR gate with the outputs 160, 170, and 320 of modules A 140, B 150, and C 310, respectively, as the three inputs, and the output 380 of the OR gate 370 as the output of the effective three-input XOR gate.

If synchronized scan tests are performed on modules A 140, B 150, and C 310 in the manner described above, and if the output 380 of the OR gate 370 is “0”, it can be assumed that the outputs 160, 170, and 320 of modules A 140, B 150, and C 310 were the same and that modules A 140, B 150, and C 310 are therefore functioning properly. If desired, traditional scan testing can be performed on only one of the modules A 140, B 150, or C 310 in the manner described above to confirm that the output 160, 170, or 320 of module A 140, B 150, or C 310 is correct, for example.

If the output 380 of the OR gate 370 contains a “1”, it can be assumed that one of the outputs 160, 170, or 320 was different from the others and therefore that one of the modules A 140, B 150, or C 310 did not function properly. Testing of the modules A 140, B 150, or C 310 individually in the manner described above can then be done to determine which module A 140, B 150, or C 310 is faulty.

FIG. 4 illustrates an embodiment of a gate array that could be used for scan testing of four substantially identical modules. Module D 410, which is substantially identical to modules A 140, B 150, and C 310, has an output 420 that feeds into XOR gate 330. The other input of XOR gate 330 is fed by the output 320 of module C 310 as in FIG. 3. Output 160 from module A 140 and output 170 from module B 150 feed into XOR gate 180. Output 190 from XOR gate 180 and output 360 from XOR gate 330 feed into XOR gate 390. The other elements present in FIG. 2 are again not shown.

Using an analysis similar to that described above, if the output 395 of the XOR gate 390 is “0”, the outputs 160, 170, 320, and 420 can be assumed to be similar and therefore modules A 140, B 150, C 310, and D 410 can be assumed to be functioning properly. A “1” on output 395 suggests that at least one module A 140, B 150, C 310, or D 410 is faulty. One of skill in the art will recognize based on the present disclosure that the use of additional logic gates in arrangements similar to those shown in FIGS. 2, 3, and 4 could be used for scan testing of additional substantially identical modules.

While several embodiments have been provided in the present disclosure, it should be understood that the system and method for Simultaneous Scan Testing for Identical Modules may be embodied in many other specific forms without departing from the spirit or scope of the present disclosure. The present examples are to be considered as illustrative and not restrictive, and the intention is not to be limited to the details given herein, but may be modified within the scope of the appended claims along with their full scope of equivalents. For example, the various elements or components may be combined or integrated in another system or certain features may be omitted, or not implemented.

Also, techniques, systems, subsystems and methods described and illustrated in the various embodiments as discrete or separate may be combined or integrated with other systems, modules, techniques, or methods without departing from the scope of the present disclosure. Other items shown or discussed as directly coupled or communicating with each other may be coupled through some interface or device, such that the items may no longer be considered directly coupled to each other but may still be indirectly coupled and in communication, whether electrically, mechanically, or otherwise with one another. Other examples of changes, substitutions, and alterations are ascertainable by one skilled in the art and could be made without departing from the spirit and scope disclosed herein.

What is claimed is:

1. A system for scan testing at least two substantially identical modules within an integrated circuit comprising:
a first module operable to receive and process scan input and produce a first scan output;
a second module substantially similar to the first module, the second module operable to receive and process scan input and produce a second scan output; and
a first component operable to receive the first and second scan outputs and produce a first output, the first output used to determine whether the first and second modules are functioning properly.

2. The system of claim 1, wherein the first component is further defined as an XOR gate, the first output of the XOR gate determining that the first and second modules are functioning properly where the first and second scan outputs are the same.

3. The system of claim 2, further comprising an analysis component operable to receive the first output and determine that the first and second modules are functioning properly based on the first output when the first and second scan outputs are the same.

4. The system of claim 1, further comprising an output selection circuit operable for isolating the one of the first and second modules for testing by manipulating one of the first and second scan outputs prior to receipt by the first component.

5. The system of claim 4, wherein the output selection circuit comprises:
an output selection component operable to place values on an output of the output selection component;
a first AND gate operable to receive and process the first scan output from the first module and a first value from the output of the first output selection component, an output of the first AND gate communicated to the first XOR gate; and
a second AND gate operable to receive and process the second scan output from the second module and a second value from the output of the first output selection component, an output of the second AND gate communicated to the first XOR gate.

6. The system of claim 4, further comprising:
a third module substantially similar to the first and second modules, the third module operable to receive and process scan input and produce a third scan output;
a second component operable to receive the first and third scan outputs and produce a second output;
a third component operable to receive the second and third scan outputs and produce a third output; and
a fourth component operable to receive the first, second, and third outputs of the first, second, and third components and produce a fourth output, the fourth output used to determine whether the first, second, and third modules are functioning properly.

7. The system of claim 6, wherein the first, second, and third components are further defined as XOR gates and the fourth component is defined as an OR gate.

8. The system of claim 1, further comprising a module selection component operable for selectively communicating signals to the first and second modules responsive to which one of the first and second modules continues processing scan inputs and the other of the first and second modules discontinues processing.

9. The system of claim 8, wherein the module selection component comprises:
a selector operable to place values on an output of the selector;
a first AND gate operable to receive and process a clock signal and a first value from the selector, an output of the first AND gate communicated to a clock input of the first module; and
a second AND gate operable to receive and process the clock signal and a second value from the selector, an output of the second AND gate communicated to a clock input of the second module.

10. A system for scan testing at least two substantially identical modules within an integrated circuit comprising:
a scan input;
a first module operable to receive and process the scan input and produce a first scan output;
a second module substantially similar to the first module, the second module operable to receive and process the scan input and produce a second scan output; and
a means for receiving the first and second scan outputs and producing a first output, the first output used to determine whether the first and second modules are functioning properly.

11. The system of claim 10, wherein the means for receiving the first and second scan inputs is further defined as an XOR gate.

12. The system of claim 10, further comprising an output selection circuit operable for isolating the one of the first and second modules for testing by manipulating one of the first and second scan outputs prior to receipt by the first component.

13. The system of claim 10, further comprising a module selection component operable for selectively communicating signals to the first and second modules responsive to which one of the first and second modules continues processes scan inputs and the other of the first and second modules discontinues processing.

14. The system of claim 10, further comprising:
a third module substantially similar to the first and second modules, the third module operable to receive and process scan input and produce a third scan output;
a second means for receiving the first and third scan outputs and producing a second output;
a third means for receiving the second and third scan outputs and producing a third output; and
a fourth means for receiving the first, second, and third outputs of the means, second means, and third means and producing a fourth output, the fourth output used to determine whether the first, second, and third modules are functioning properly.

15. A method for determining whether at least two substantially identical modules within an integrated circuit are functioning properly, the method comprising:
sending a scan input to a first module and a second module;
producing a first scan output by the first module;
producing a second scan output by the second module;
sending the first and second scan outputs to a first component;
producing a first output by the first component; and
using the first output to determine whether the first and second modules are functioning properly.

16. The method of claim 15, wherein the first component is further defined as an XOR gate.

17. The method of claim 15, further comprising concluding that the first and second modules are functioning properly when the first output indicates that the first and second scan outputs are the same.

18. The method of claim 15, further comprising providing a module selection component operable for selectively communicating signals to the first and second modules responsive to which one of the first and second modules continues processes scan inputs and the other of the first and second modules discontinues processing.

19. The method of claim 15, further comprising providing an output selection circuit operable for isolating the one of the first and second modules for testing by manipulating one of the first and second scan outputs prior to receipt by the first component.

20. The method of claim 15, further comprising:
sending the scan input to a third module;
producing a third scan output by the third module;
sending the first and third scan outputs to a second component producing a second output by the second component;
sending the second and third scan outputs to a third component;
producing a third output by the third component;
sending the first, second, and third outputs from the first, second, and third components to a fourth component;
producing a fourth output by the fourth component; and
using the fourth output to determine whether the first, second, and third modules are functioning properly.
